(19) United States
(12) Patent Application Publication
(10) Pub. No.: US 2025/0089287 A1
(43) Pub. Date: Mar. 13, 2025

(54) CHARGE-SENSING SEMICONDUCTOR DEVICE WITH DELTA LAYER TUNNEL JUNCTION

(71) Applicant: National Technology & Engineering Solutions of Sandia, LLC, Albuquerque, NM (US)

(72) Inventors: Denis Mamaluy, Albuquerque, NM (US); Juan Pedro Mendez Granado, Albuquerque, NM (US)

(21) Appl. No.: 18/243,453

(22) Filed: Sep. 7, 2023

(51) Int. Cl. H01L 29/76; H01L 29/08; H01L 29/66

(52) U.S. Cl. CPC H10D 30/402; H10D 30/014; H10D 62/165

(57) ABSTRACT

A charge-sensing semiconductor device is provided. The device comprises a substrate body, a source formed along a first sidewall of the substrate body, and a drain formed along a second sidewall of the substrate body. A first and a second delta layer are disposed on the substrate body and are separated by a gap. The first delta layer is in contact with the source and the second delta layer is in contact with the drain. A cap is disposed over the first and second delta layers. The first and second delta layers are embedded between the substrate body and the cap. The first and second delta layers are formed by thin layers of phosphorus, and the substrate body and the cap are formed of a semiconductor material.

### STATEMENT OF GOVERNMENT INTEREST

This invention was made with United States Government support under Contract No. DE-NA0003525 awarded by the United States Department of Energy/National Nuclear Security Administration. The United States Government has certain rights in this invention.

### BACKGROUND

### 1. Field

The disclosure relates generally to charge-sensing devices, and more specifically to a charge-sensing semiconductor device with a delta layer tunnel junction.

### 2. Description of the Related Art

Charge-sensing devices such as single electron transistors (SETs) are used in various fields due to their exceptional sensitivity to small changes in charge. For example, in quantum information processing, charge-sensing devices can be integrated into quantum computers to read out the states of qubits. The ability of charge-sensing devices to detect individual electron charges makes them suitable for measuring quantum states and performing quantum error correction. Charge-sensing devices are also used as sensors and detectors. For example, SETs can detect the presence of individual nanoparticles by measuring the changes in charge they cause on a nearby island.

Existing charge-sensing devices based on SETs have several drawbacks. Because SETs typically have three electrodes (e.g., source, drain and gate), fabrication of the SETs is complex and intricate. During the fabrication process, precise control over nanometer-scale features and dopant placement is required, which can increase manufacturing costs of such devices. Also, SET-based charge-sensing devices generally require a very small, nanometer-scale, conductive island, which can be challenging to achieve. Creating and maintaining such nanometer-scale conductive island requires precise control over device dimensions and material properties.

### SUMMARY

An illustrative embodiment provides a charge-sensing semiconductor device. The device comprises a substrate body, a source formed along a first sidewall of the substrate body, and a drain formed along a second sidewall of the substrate body. A first and a second delta layer are disposed on the substrate body and are separated by a gap. The first delta layer is in contact with the source and the second delta layer is in contact with the drain. A cap is disposed over the first and second delta layers. The first and second delta layers are embedded between the substrate body and the cap.

In an illustrative embodiment, the first and second delta layers are formed by thin layers of phosphorus, and the substrate body and the cap are formed of a semiconductor material. The gap separating the two delta layers has a controlled width to enable tunable charge sensing capability. The substrate body is formed using a crystal silicon wafer.

Another illustrative embodiment provides a method of fabricating a charge-sensing semiconductor device. The method comprises forming a substrate body using a semiconductor material and doping the substrate body to introduce controlled amounts of dopants for controlling electrical properties of the device. The method comprises passivating a surface of the substrate body. The method comprises forming a first delta layer in contact with the source and a second delta layer in contact with the drain on the substrate body. The first and second delta layers are separated by a gap, wherein the gap has a controlled width for tunable charge sensing capability. The method comprises depositing a cap over the first and second delta layers to embed the delta layers between the substrate body and the cap. The method comprises forming a source in a first region of the substrate body and forming a drain in a second region of the substrate body.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 illustrates a cross-sectional view of a charge-sensing device in accordance with an illustrative embodiment;

FIG. 2 illustrates a perspective view of a charge-sensing device in accordance with an illustrative embodiment;

FIG. 3 illustrates charge sensing capabilities of a device in accordance with an illustrative embodiment;

FIG. 4A illustrates energy levels along an axis of the devices of FIGS. 2 and 3;

FIG. 4B illustrates a plot of a current ratio vs. thickness of a delta layer of the devices of FIGS. 2 and 3;

FIG. 5 illustrates a magnitude of current versus the position of a charged entity in a device in accordance with an illustrative embodiment;

FIG. 6 illustrates a rate of change of current versus a position of a charged entity in a device in accordance with an illustrative embodiment; and

FIG. 7 is a flowchart of a process for fabricating a charge-sensing device in accordance with an illustrative embodiment.

### DETAILED DESCRIPTION

The illustrative embodiments recognize and take into account one or more different considerations. For example, the illustrative embodiments recognize and take into account that existing SET-based charge-sensing devices typically have three electrodes, which increases manufacturing costs. The illustrative embodiments also recognize and take into account that during fabrication of existing charge-sensing devices, precise control over nanometer-scale features and dopant placement is required, which can increase manufacturing costs. The illustrative embodiments also recognize and take into account that existing SET-based charge-sensing devices generally require a very small, nanometer-scale, conductive island, which can be challenging to achieve. Creating and maintaining such nanometer-scale gaps requires precise control over device dimensions and material properties.

The illustrative embodiments provide a charge-sensing semiconductor device with a delta layer tunnel junction. The charge-sensing device includes a source and a drain but does not include a gate which is typically present in existing SET-based charge-sensing devices. Because the charge-sensing device of the illustrative embodiments include only two electrodes instead of three electrodes, manufacturing complexity and costs are reduced. Also, unlike existing charge-sensing devices, the illustrative embodiments do not require a conductive island.

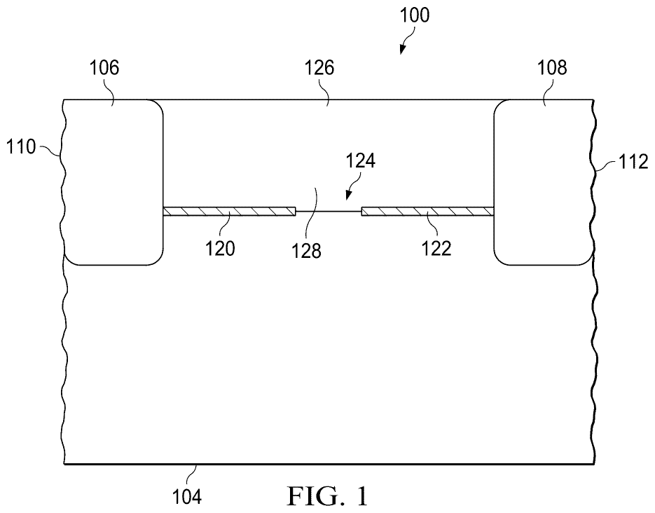

FIG. 1 illustrates a cross-sectional view of charge-sensing semiconductor device 100 in accordance with an illustrative embodiment. Device 100 includes substrate body 104 which acts as a foundation and provides structural support to device 100. In one example implementation, substrate body 104 is formed using a crystal silicon wafer, which serves as the base material for the fabrication of device 100. Substrate body 104 may undergo a doping step, which involves introducing controlled amounts of specific impurities (dopants) to control electrical properties such as the conductivity of substrate body 104. In one illustrative embodiment, substrate body 104 is doped with a p-type dopant such as boron (B).

Substrate body 104 maintains the physical integrity of the structure of device 100 and prevents mechanical stress and deformation. Also, substrate body 104 serves as a reference potential and may be electrically connected to a reference voltage (e.g., ground).

Device 100 includes source 106 and drain 108. Source 106 may be formed in a region along sidewall 110 of substrate body 104. Drain 108 may be formed in a region along sidewall 112 of substrate body 104. In some example embodiments, source 106 and drain 108 may be formed by heavily doping regions of substrate body 104 (e.g., Si). Thus, source 106 and drain 108 may be formed using the same semiconductor material as substrate body 104 but with a much higher level of doping. In some example embodiments, source 106 and drain 108 may be made of a metal or a silicide compound.

Device 100 includes first delta layer 120 and second delta layer 122 disposed on substrate body 104. First delta layer 120 is in contact with source 106, and second delta layer 122 is in contact with drain 108. First delta layer 120 and second delta layer 122 are separated by gap 124. In some example embodiments, first delta layer 120 and second delta layer 122 are formed by thin layers of phosphorus. In some example embodiments, techniques such as atomic precision advance manufacturing (APAM) or photolithography may be used to form first delta layer 120 and second delta layer 122.

Device 100 includes cap 126 disposed over first delta layer 120 and second delta layer 122. Cap 126 is made of the same semiconductor material as substrate body 104. Thus, first delta layer 120 and second delta layer 122 extend from source 106 and drain 108, respectively, and are embedded between substrate body 104 and cap 126. In one illustrative embodiment, cap 126 is doped with a p-type dopant such as boron (B).

First delta layer 120 and second delta layer 122 form tunnel junction 128 near gap 124. Tunnel junction 128 is a structure that facilitates controlled tunneling of individual electrons between source 106 and drain 108. Due to a quantum mechanical phenomenon, electrons can tunnel (i.e., pass) through tunnel junction 128 that would be normally impassable in classical mechanics. In a semiconductor device, tunneling is exploited to allow controlled transport of electrons.

Device 100 may be packaged as an integrated circuit (IC) (not shown in FIG. 1). Bond wires made of gold or aluminum or other suitable conductor can be used to connect source 106 and drain 108 to bonding pads on a lead-frame (not shown in FIG. 1). The wires establish electrical connections between device 100 and external circuitry.

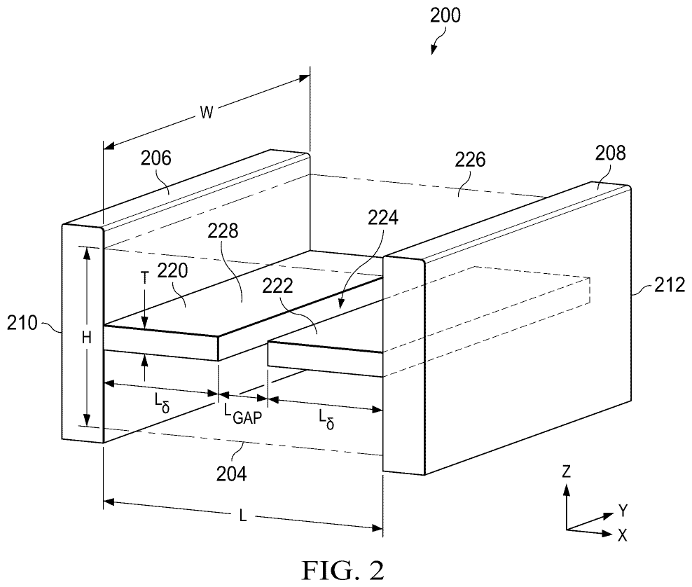

FIG. 2 illustrates a perspective view of charge-sensing semiconductor device 200 in accordance with an illustrative embodiment. Device 200 includes substrate body 204 which acts as a foundation and provides structural support to device 200. Substrate body 204 may be formed using a semiconductor material such as silicon (Si) which may be doped with a dopant such as boron (B).

Device 200 includes source 206 and drain 208. Source 206 may be formed in a region along sidewall 210 of substrate body 204. Drain 208 may be formed in a region along sidewall 212 of substrate body 204. In some example embodiments, source 206 and drain 208 may be formed by heavily doping regions of substrate body 204 (e.g., Si). In other embodiments, source 206 and drain 208 can be made of a metal or a silicide compound.

Device 200 includes first delta layer 220 and second delta layer 222 disposed on substrate body 204. First delta layer 220 is in contact with source 206, and second delta layer 222 is in contact with drain 208. First delta layer 220 and second delta layer 222 are separated by gap 224. In some example embodiments, first delta layer 220 and second delta layer 222 are formed by thin layers of phosphorus. As discussed below, the thickness of the delta layers affects the sensitivity of the device. If the delta layers are very thin, device 200 is sensitive to the presence of charged entities around gap 224.

Device 200 includes cap 226 disposed over first delta layer 220 and second delta layer 222. First delta layer 220 and second delta layer 222 extend from source 206 and drain 208, respectively, and are embedded between substrate body 204 and cap 226. In one illustrative embodiment, cap 226 is doped with a p-type dopant.

In the illustrative embodiment of FIG. 2, device 200 has the following dimensions: (1) length L which is defined as the distance between source 206 and drain 208; (2) height H which is defined as the height of source 206 or drain 208; (3) gap L_{GAP} which is defined as the length of gap 224; and (4) delta length L_{DELTA} which is defined as the length of the delta layers.

In some example embodiments, L_{GAP} separating first delta layer 220 and second delta layer 222 has a controlled width to enable tunable charge sensing capability. L_{GAP} can be varied by increasing or decreasing the length of the delta layers. In one illustrative embodiment, L_{GAP} is between 7 nm and 20 nm.

In some example embodiments, the length L is around 40 nm, the height H is around 8 nm and the thickness of first delta layer 220 and second delta layer 222 is between 0.2 nm and 5 nm.

First delta layer 220 and second delta layer 222 form tunnel junction 228 near gap 224. Tunnel junction 228 is a structure that facilitates controlled tunneling of individual electrons between source 206 and drain 208.

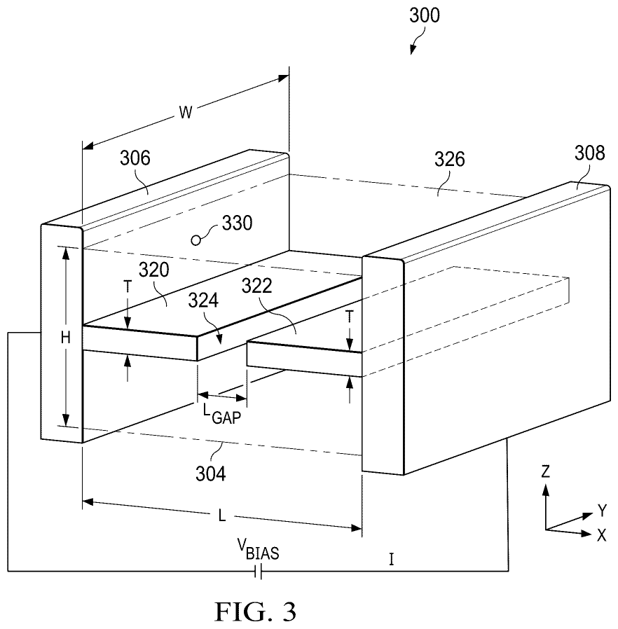

FIG. 3 illustrates charge sensing capabilities of device 300 in accordance with an illustrative embodiment. Device 300 includes substrate body 304 which acts as a foundation and provides structural support to device 300. Device 300 includes source 306 and drain 308. Device 300 includes first delta layer 320 and second delta layer 322 disposed on substrate body 304. First delta layer 320 is in contact with source 306, and second delta layer 322 is in contact with drain 308. First delta layer 320 and second delta layer 322 are separated by gap 324. Device 300 includes cap 326 disposed over first delta layer 320 and second delta layer 322. A bias voltage V_{BIAS} in the range of a few mV to about 1V is applied between drain 308 and source 306.

In the illustrative embodiment of FIG. 3, charged entity 330 is present in a region of cap 326 or may be present on the surface of cap 326. Charged entity 330 may be a single donor atom of an element which is placed in cap 326 using, for example, a scanning tunneling microscope or may be a permanent charged defect created due to an effect of a radiation. Charged entity 330 can also be a charged nanoparticle or a molecule placed on the surface of cap 326. When charged entity 330 is placed away from gap 324 and near source 306 or drain 308, the tunneling current between first delta layer 320 and second delta layer 322 is not affected when bias voltage V_{BIAS} is applied. As charged entity 330 is placed closer and closer to gap 324, quantum effect becomes more pronounced, which results in a significant variation of the tunneling current, signaling the presence of the charged entity.

Device 300 takes advantage of discrete and continuous energy level behavior to detect static or dynamic charged entities near and away from gap 324. If the bias voltage V_{BIAS} is applied between source 306 and drain 308, a small amount of current I_{REF} flows between source 306 and drain 308. If charged entity 330 is away from gap 324 and near source 306 or drain 308, the resulting current I between drain 308 and source 306 is approximately equal to I_{REF}. As charged entity 330 is closer and closer to gap 324, the current I between drain 308 and source 306 changes. By comparing I and I_{REF}, the presence or absence of charged entity 330 can be determined. If I is approximately equal to I_{REF}, the likely absence of charged entity 330 is indicated. If I is higher than I_{REF}, the likely presence of n-type charged entity 330 is indicated. Also, by measuring the rate of change of I, the location of charged entity 330 can be determined. In some example embodiments, if the charged entity is a p-type charge, current I decreases relative to I_{REF}.

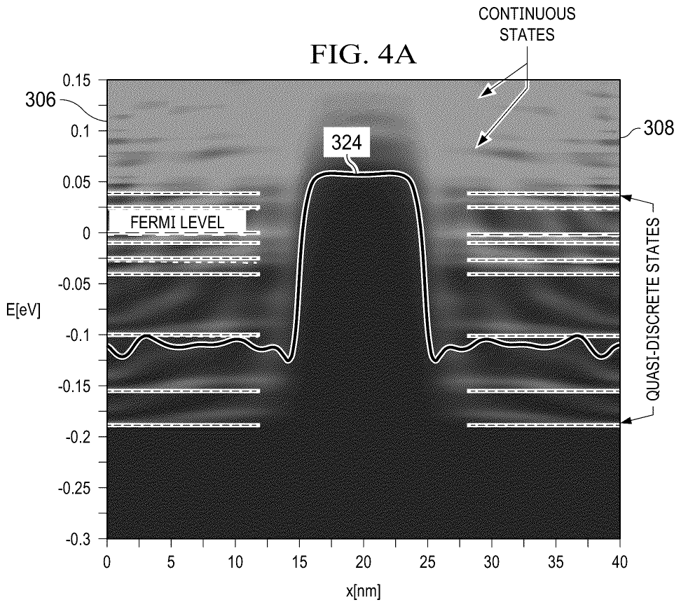

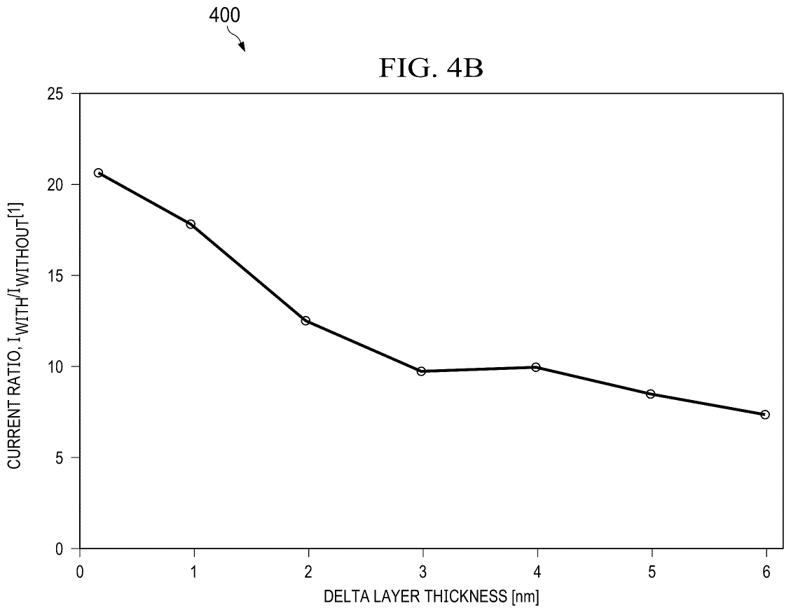

FIG. 4A illustrates energy levels along the x-axis in device 200 and device 300. The energy levels are also known as local density of states (LDOS (x, E)). In FIG. 4A, states between x=0 nm and x=15 nm correspond to the first delta layer region, states between x=25 nm and x=40 nm correspond to the second delta layer region, and states between x=15 nm and x=25 nm correspond to the gap between the delta layer regions.

At low temperature, states below the Fermi level are occupied by electrons and the states above the Fermi level are unoccupied. As the temperature increases, some states above the Fermi level start to be occupied to the detriment of the states below the Fermi level. In the delta layer regions (e.g., between x=0 nm and x=15 nm and between x=25 nm and x=40 nm), the low-energy LDOS (x, E) are strongly quantized, indicated by dashed lines, for energies below the Fermi level and approximately up to 50 meV above the Fermi level. For high energies (e.g., above 50 meV), the LDOS (x,E) are continuous in space-energy, and as such these states are not quantized. As a consequence of quantized states in the delta layer regions, any perturbation (e.g., due to a presence of a charged entity) near the gap results in a significant variation of the tunneling rate from one delta layer to the other when a voltage is applied between the source and the drain.

FIG. 4B illustrates plot 400 of a current ratio I_{with}/I_{without} vs. thickness of the delta layer, where I_{with} is a current in the presence of a charged entity and I_{without} is a current without the presence of a charged entity. The x-axis represents the thickness of the delta layers and the y-axis represents the current ratio I_{with}/I_{without}. In this example, a bias voltage V_{BIAS}=100 mV is applied between the drain and the source. As illustrated in FIG. 4B, the thickness of the delta layers affects the current ratio, which affects the sensitivity of device 200 and device 300. In the present disclosure, the sensitivity of device 200 and device 300 is defined as the deviation of I_{without} from I_{with}. As the thickness of the delta layers increases, device 200 and device 300 become less sensitive.

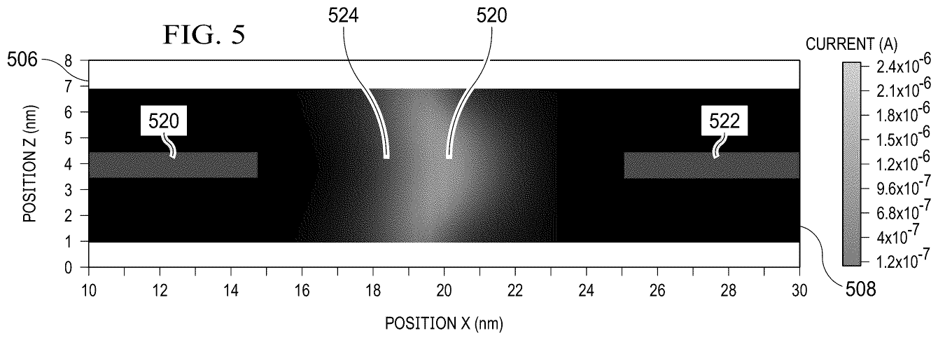

FIG. 5 illustrates a magnitude of current versus the position of a charged entity (e.g., a single electron) in device 300 in accordance with an illustrative embodiment. Delta layers 520 and 522 are separated by gap 524. A charged entity can be present in a region between source 506 and drain 508. The position of the charged entity can be indicated with reference to the x-axis and the z-axis, and the magnitude of the current between drain 508 and source 506 is indicated by the intensity of light 540. A bias voltage of 100 mV (not shown in FIG. 5) is applied between source 506 and drain 508. If the charged entity is away from gap 524 and near source 506 or drain 508, the current between drain 508 and source 506 is low as indicated by the dark regions. As the charged impurity is placed closer and closer to gap 524, the current rises rapidly as indicated by the increasing intensity of light 540.

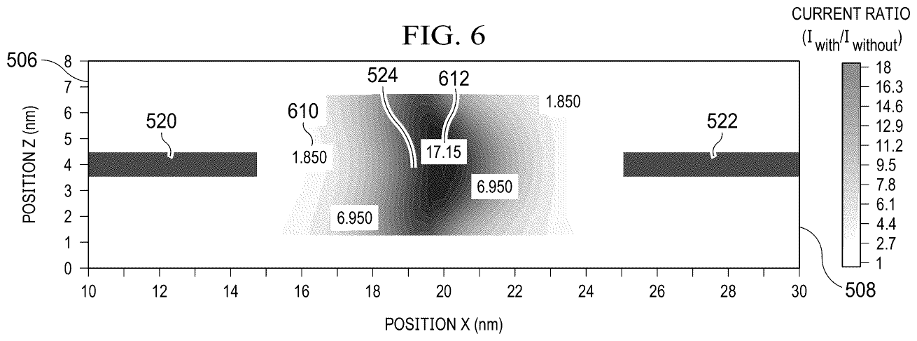

FIG. 6 illustrates a rate of change of the magnitude of current versus the position of a charged entity in device 300 in accordance with an illustrative embodiment. A charged entity can be present in the region between source 506 and drain 508. The position of the charged entity is indicated with reference to the x-axis and the z-axis. If the charged entity is placed away from gap 524 and near source 506 or drain 508, the current between drain 508 and source 506 is very low. As the charged impurity is placed closer and closer to gap 524, the current changes rapidly. For example, if the charged impurity is placed at location 610, the current increases by 185%. If the charged impurity is placed at location 612, the current increases by 1715%. Because device 300 is very sensitive to the presence and location of the charged entity, device 300 can be used to determine the presence as well as the location of the charged entity.

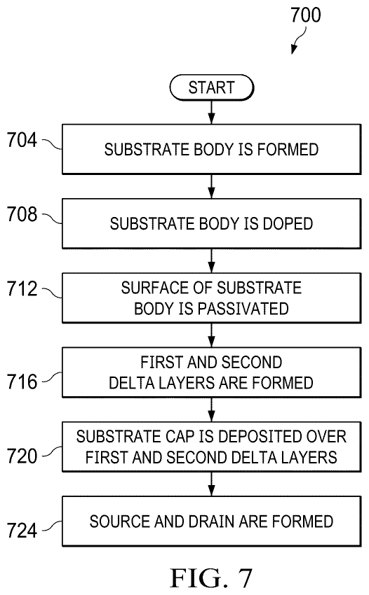

With reference next to FIG. 7, a flowchart of process 700 for fabricating device 100, device 200 or device 300 is depicted in accordance with an illustrative embodiment. A substrate body (e.g., substrate body 104) is formed using a semiconductor material such as silicon (step 704). In one example implementation, the substrate body is formed using a crystal silicon wafer, which serves as the base material for the fabrication of a charge-sensing device. The substrate body may undergo a doping step (step 708). Doping involves introducing controlled amounts of specific impurities (dopants) to control electrical properties such as the conductivity of the substrate body.

The surface of the substrate body is then passivated with hydrogen atoms (step 712). In some example embodiments, passivation of the substrate body may involve exposing the surface to hydrogen gas.

Next, first and second delta layers are formed on the substrate body (step 716). In some example implementations, the delta layers are formed by removing the hydrogen atoms from selected surface areas of the substrate body and depositing a layer of phosphorus on the selected surface areas. A cap (e.g., cap 126) is deposited over the first and second delta layers (step 720). The cap is made of the same semiconductor material as the substrate body. Thus, the delta layers are embedded between the substrate body and the cap.

A source (e.g., source 106) is formed in a region along a first sidewall of the substrate body, and a drain (e.g., drain 108) is formed in a region along a second sidewall of the substrate body (step 724). In some example embodiments, the source and the drain may be formed by heavily doping regions of the substrate body, or they can be made of a metal.

The first delta layer (e.g., delta layer 120) is in contact with the source, and the second delta layer (e.g., delta layer 122) is in contact with the drain. The first and second delta layers are separated by a gap (e.g., gap 124). The gap separating the two delta layers has a controlled width to enable tunable charge sensing capability. The length of the gap can be varied by increasing or decreasing the length of the delta layers.

As used herein, the phrase “a number” means one or more. The phrase “at least one of”, when used with a list of items, means different combinations of one or more of the listed items may be used, and only one of each item in the list may be needed. In other words, “at least one of” means any combination of items and number of items may be used from the list, but not all of the items in the list are required. The item may be a particular object, a thing, or a category.

For example, without limitation, “at least one of item A, item B, or item C” may include item A, item A and item B, or item C. This example also may include item A, item B, and item C or item B and item C. Of course, any combinations of these items may be present. In some illustrative examples, “at least one of” may be, for example, without limitation, two of item A; one of item B; and ten of item C; four of item B and seven of item C; or other suitable combinations.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks may be implemented as program code.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component. Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A charge-sensing semiconductor device, comprising:
a substrate body;
a source formed along a first sidewall of the substrate body;
a drain formed along a second sidewall of the substrate body;
first and second delta layers disposed on the substrate body and separated by a gap, wherein the first delta layer is in contact with the source and the second delta layer is in contact with the drain; and
a cap disposed over the first and second delta layers.

2. The charge-sensing semiconductor device of claim 1, wherein the first and second delta layers are embedded between the substrate body and the cap.

3. The charge-sensing semiconductor device of claim 1, wherein the gap is embedded between the substrate body and the cap.

4. The charge-sensing semiconductor device of claim 1, wherein the first and second delta layers are formed by thin layers of phosphorus.

5. The charge-sensing semiconductor device of claim 1, wherein the substrate body and the cap are formed of a semiconductor material.

6. The charge-sensing semiconductor device of claim 1, wherein the substrate body and the cap are formed of silicon doped with a dopant.

7. The charge-sensing semiconductor device of claim 1, wherein the source and the drain are formed of a semiconductor material doped with a dopant.

8. The charge-sensing semiconductor device of claim 1, wherein the first delta layer extends from the source into a region between the substrate body and the cap, and wherein the second delta layer extends from the drain into another region between the substrate body and the cap.

9. The charge-sensing semiconductor device of claim 1, wherein the gap separating the two delta layers has a controlled width to enable tunable charge sensing capability.

10. The charge-sensing semiconductor device of claim 1, wherein the gap separating the two delta layers is between 4 nano-meters and 20 nano-meters.

11. The charge-sensing semiconductor device of claim 1, wherein the thickness of the delta layers is between 0.2 and 5 nm.

12. A charge-sensing semiconductor device, comprising:
a substrate body;
a source formed along a first sidewall of the substrate body;
a drain formed along a second sidewall of the substrate body;
first and second delta layers disposed on the substrate body and separated by a gap, wherein the first delta layer is in contact with the source and the second delta layer is in contact with the drain; and
a cap disposed over the first and second delta layers, wherein the first and second delta layers are embedded between the substrate body and the cap, and wherein the gap separating the first and second delta layers has a controlled width to enable tunable charge sensing capability.

13. The charge-sensing semiconductor device of claim 12, wherein the first and second delta layers are formed by thin layers of phosphorus.

14. The charge-sensing semiconductor device of claim 12, wherein the substrate body and the cap are formed of a semiconductor material.

15. The charge-sensing semiconductor device of claim 12, wherein the substrate body and the cap are formed of silicon doped with a dopant.

16. The charge-sensing semiconductor device of claim 12, wherein the source and the drain are formed of a semiconductor material doped with a dopant.

17. A method for fabricating a charge-sensing semiconductor device, comprising:
forming a substrate body using a semiconductor material;
doping the substrate body to introduce controlled amounts of dopants for controlling electrical properties of the device;
passivating a surface of the substrate body;
forming a first delta layer and a second delta layer on the substrate body, the first and second delta layers separated by a gap;
depositing a cap over the first and second delta layers to embed the delta layers between the substrate body and the cap; and
forming a source in a first region of the substrate body and forming a drain in a second region of the substrate body, wherein the source is in contact with the first delta layer and the drain is in contact with the second delta layer.

18. The method of claim 17, wherein the substrate body is formed using a crystal silicon wafer.

19. The method of claim 17, wherein the passivating a surface of the substrate body comprises exposing the surface to hydrogen gas.

20. The method of claim 17, wherein the length of the gap is variably adjusted by varying the lengths of the first and second delta layers.

21. The method of claim 17, wherein the first and second delta layers are formed by thin layers of phosphorus.

22. The method of claim 17, wherein the source and the drain are formed of the semiconductor material doped with a dopant.
